(19) United States
(12) Patent Application Publication
(10) Pub. No.: US 2017/0280572 A1
(43) Pub. Date: Sep. 28, 2017

(54) ELECTRONIC DEVICE

(71) Applicant: KYOCERA CORPORATION, Kyoto (JP)

(72) Inventor: Hiroyoshi KAWANISHI, Sanda-shi (JP)

(21) Appl. No.: 15/466,511

(22) Filed: Mar. 22, 2017

(30) Foreign Application Priority Data
Mar. 25, 2016 (JP) 2016-061541

(51) Int. Cl. H05K 5/02; A45C 5/00; A45C 13/00; H05K 5/03; A45C 11/00

(52) U.S. Cl. CPC H05K 5/0217; H05K 5/03; A45C 11/00; A45C 13/002; A45C 5/00; A45C 13/008; A45C 2011/001; A45C 2011/002; A45C 2011/003

(57) ABSTRACT

An electronic device includes a housing including a through hole, a sheet which is impermeable to water, permeable to air, and located to cover the through hole, and a cover which is attached to the housing and partially covers an outer surface of the housing while the cover covers the through hole. The housing includes a first portion not covered with the cover even while the cover is attached to the housing. The cover and the housing include at least one recess and at least one projection which can be fitted to the recess, in any of them respectively, so as to function as a shield in at least a part between the first portion and the through hole.

### CROSS-REFERENCE TO RELATED APPLICATION

The present application claims priority under 35 U.S.C. §119 to Japanese Patent Application No. 2016-061541 filed on Mar. 25, 2016, entitled “Electronic Device”. The content of which is incorporated by reference herein in its entirety.

### FIELD

The present disclosure relates to an electronic device.

### BACKGROUND

A waterproof electronic device has been known. Such an electronic device may include a barometric pressure regulation sheet for easing sudden change in internal pressure.

### SUMMARY

An electronic device based on the present disclosure includes a housing including a through hole, a sheet which is impermeable to water, permeable to air, and located to cover the through hole, and a cover which is attached to the housing and partially covers an outer surface of the housing while the cover covers the through hole. The housing includes a first portion not covered with the cover even while the cover is attached to the housing. The cover and the housing include a fitting portion where at least one recess and at least one projection are fitted to each other so as to function as a shield in at least a part between the first portion and the through hole.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a perspective view of an electronic device in a first embodiment based on the present disclosure.

FIG. 2 is a plan view of the electronic device in the first embodiment based on the present disclosure.

FIG. 3 is a cross-sectional view along the line III-III in FIG. 2.

FIG. 4 is an enlarged view of a Z1 portion in FIG. 3.

FIG. 5 is a partially enlarged cross-sectional view of a housing included in the electronic device in the first embodiment based on the present disclosure.

FIG. 6 is a partially enlarged cross-sectional view of a cover included in the electronic device in the first embodiment based on the present disclosure.

FIG. 7 is a perspective view of the electronic device in the first embodiment based on the present disclosure from which the cover has been removed.

FIG. 8 is an enlarged view of a Z2 portion in FIG. 7.

FIG. 9 is a partially enlarged plan view of a portion in the vicinity of a through hole with the cover having been removed from the electronic device in the first embodiment based on the present disclosure.

FIG. 10 is a diagram illustrating a virtual path of entry of a detergent into a sheet in the electronic device in the first embodiment based on the present disclosure.

FIG. 11 is a diagram illustrating with hatching in a plan view, a space defined by a fitting portion and the like of the electronic device in the first embodiment based on the present disclosure.

FIG. 12 is a diagram illustrating with hatching in a cross-sectional view, the space defined by the fitting portion and the like of the electronic device in the first embodiment based on the present disclosure.

FIG. 13 is a diagram illustrating a path through which the detergent travels in the electronic device in the first embodiment based on the present disclosure.

FIG. 14 is a diagram illustrating a first example of positional relation among the first portion, the fitting portion, and the through hole when viewed two-dimensionally.

FIG. 15 is a diagram illustrating a second example of positional relation among the first portion, the fitting portion, and the through hole when viewed two-dimensionally.

FIG. 16 is a diagram illustrating a third example of positional relation among the first portion, the fitting portion, and the through hole when viewed two-dimensionally.

FIG. 17 is a diagram illustrating a fourth example of positional relation among the first portion, the fitting portion, and the through hole when viewed two-dimensionally.

FIG. 18 is a diagram illustrating a fifth example of positional relation among the first portion, the fitting portion, and the through hole when viewed two-dimensionally.

### DETAILED DESCRIPTION

A dimensional ratio shown in the drawings does not necessarily faithfully represent an actual dimensional ratio and a dimensional ratio may be exaggerated for the sake of convenience of description. A concept up or upper or down or lower mentioned in the description below does not mean absolute up or upper or down or lower but may mean relative up or upper or down or lower in terms of a shown position.

### First Embodiment

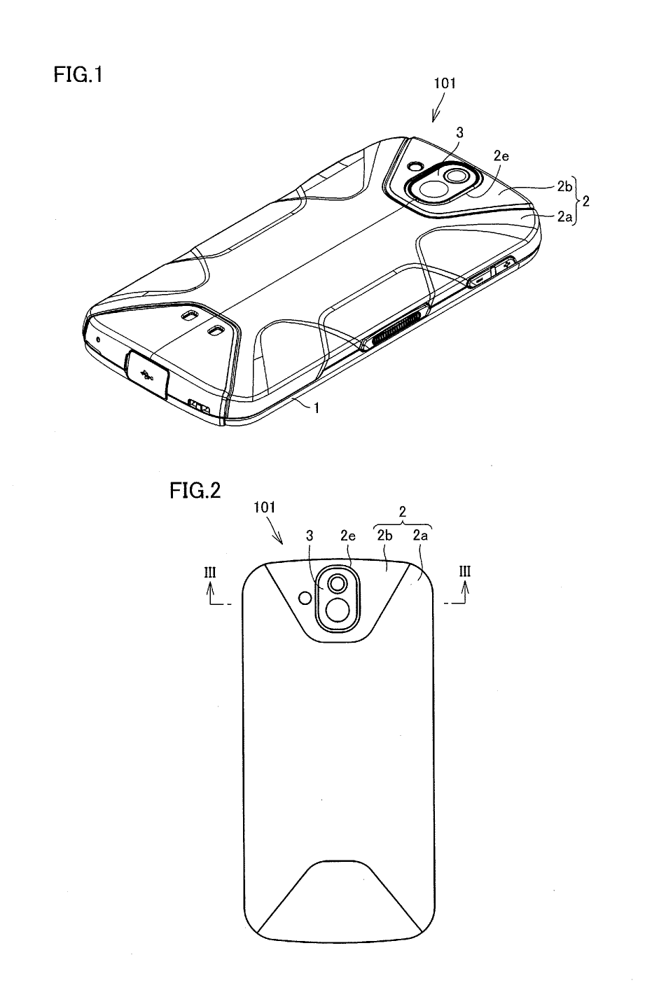

An electronic device in a first embodiment based on the present disclosure will be described with reference to FIGS. 1 to 9. FIG. 1 shows a perspective view of an electronic device 101 in the first embodiment. Electronic device 101 includes a housing 1 and a cover 2. Electronic device 101 may encompass a concept of a front side where a display is located and a rear side opposite thereto. FIG. 1 mainly shows a view of the rear side. FIG. 2 shows a plan view from the rear side of electronic device 101. Housing 1 includes a first portion 3. In the example shown in FIGS. 1 and 2, cover 2 includes an opening 2e. First portion 3 is exposed to the outside through opening 2e. First portion 3 may include, for example, a camera. First portion 3 may include, for example, a sensor. First portion 3 may include, for example, a light. Though first portion 3 is exposed to the outside through opening 2e, first portion 3 may be exposed to the outside through some kind of a cut instead of opening 2e.

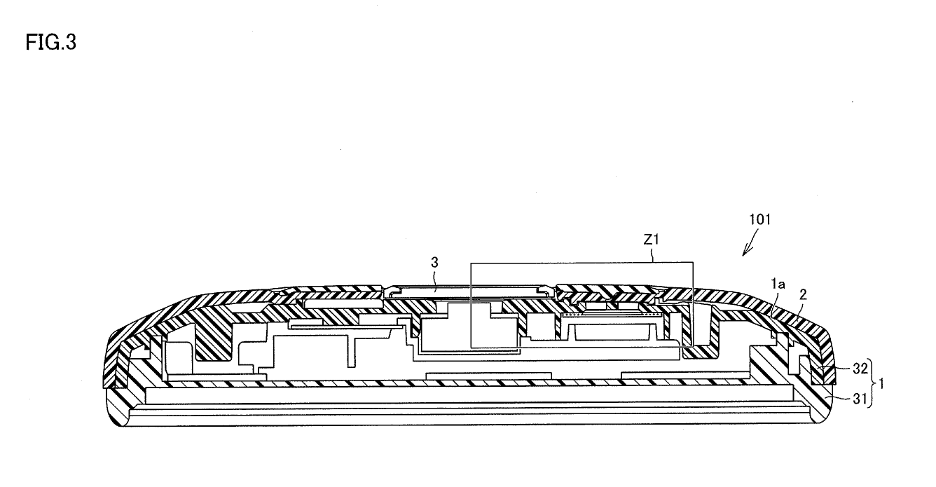

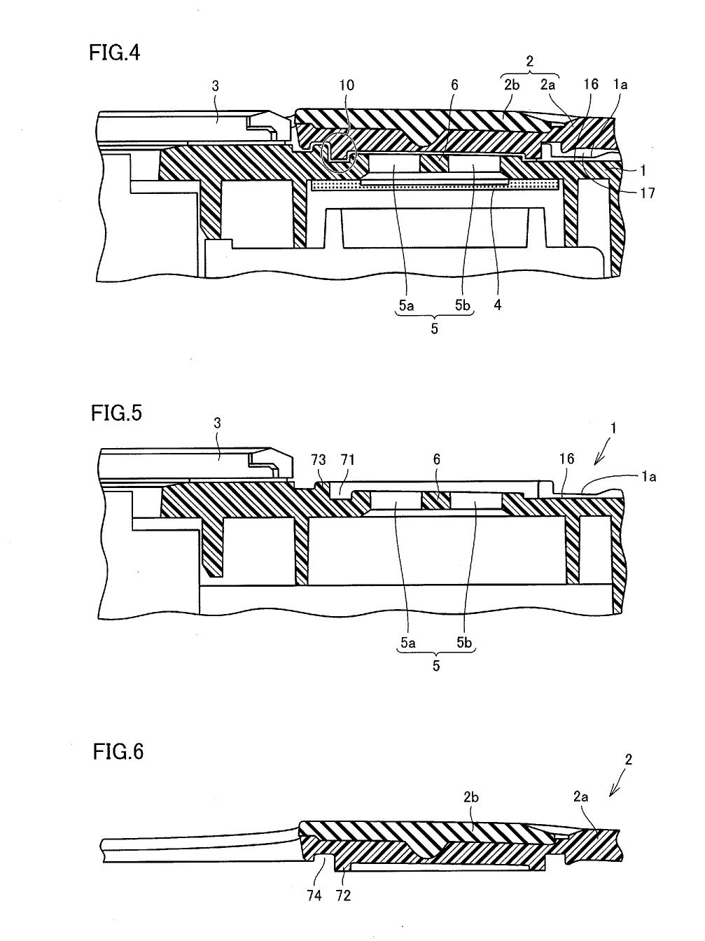

FIG. 3 shows a cross-sectional view along the line III-III in FIG. 2. FIG. 4 shows a Z1 portion in FIG. 3 as being enlarged.

In the example shown in the first embodiment, cover 2 includes a first cover portion 2a and a second cover portion 2b. First cover portion 2a and second cover portion 2b may be made of materials different from each other. First cover portion 2a and second cover portion 2b may be made, for example, of resins different in hardness from each other. First cover portion 2a and second cover portion 2b may be integrated with each other through two-color molding. First portion 3 is exposed without being covered with cover 2. In the example shown in the first embodiment, as shown in FIG. 3, housing 1 includes a front housing 31 and a rear housing 32, which merely represent examples of the “housing”. The housing may be made of a single component or three or more components.

Electronic device 101 in the first embodiment includes housing 1 including a through hole 5, a sheet 4 located to cover through hole 5, and cover 2 which is attached to housing 1 and partially covers an outer surface la of housing 1 while it covers through hole 5. Cover 2 may removably be attached to housing 1. Housing 1 includes first portion 3 not covered with cover 2 even while cover 2 is attached to housing 1. Cover 2 and housing 1 include at least one recess and at least one projection which can be fitted to the recess, in any of them respectively, so as to function as a shield in at least a part between first portion 3 and through hole 5.

In the example shown here, cover 2 and housing 1 include a fitting portion 10 (see FIG. 4) where at least one recess and at least one projection are fitted to each other. Fitting portion 10 functions as a shield in at least a part between first portion 3 and through hole 5 when viewed from above in FIG. 4. FIG. 4 shows that a groove 16 in an upper surface of housing 1 extends on the right side in the figure.

Though housing 1 and cover 2 are combined with each other in FIG. 4, FIG. 5 shows only housing 1 as being extracted. FIG. 5 shows only an area substantially the same as the area shown in FIG. 4, of the entire housing 1. FIG. 6 shows only cover 2 as being similarly extracted. FIG. 6 shows only an area substantially the same as the area shown in FIG. 4, of the entire cover 2. As shown in FIG. 5, housing 1 includes a recess 71 and a projection 73. As shown in FIG. 6, cover 2 includes a projection 72 and a recess 74. Fitting portion 10 shown as one example in FIG. 4 refers to a portion where recess 71 and projection 72 are fitted to each other so as to function as a shield in at least a part between first portion 3 and through hole 5. A cross-sectional shape of fitting portion 10 is not limited to the shape shown in FIG. 4 but another shape may be applicable. In the first embodiment, in addition to fitting of recess 71 and projection 72 to each other, on an outer side thereof, projection 73 and recess 74 are fitted to each other. Combination of recess 71, projection 72, projection 73, and recess 74 may be regarded as fitting portion 10.

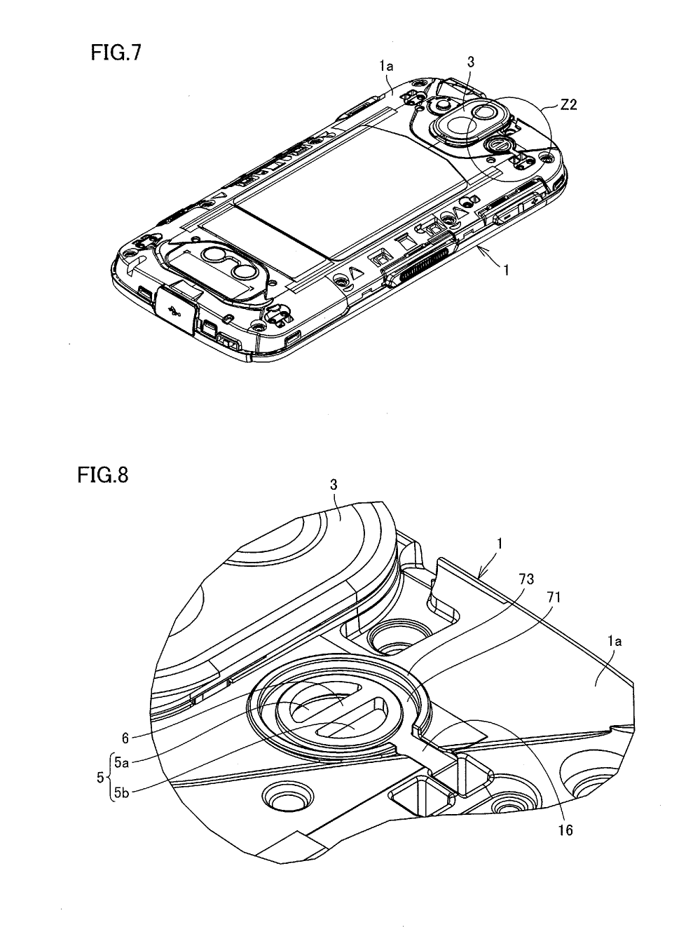

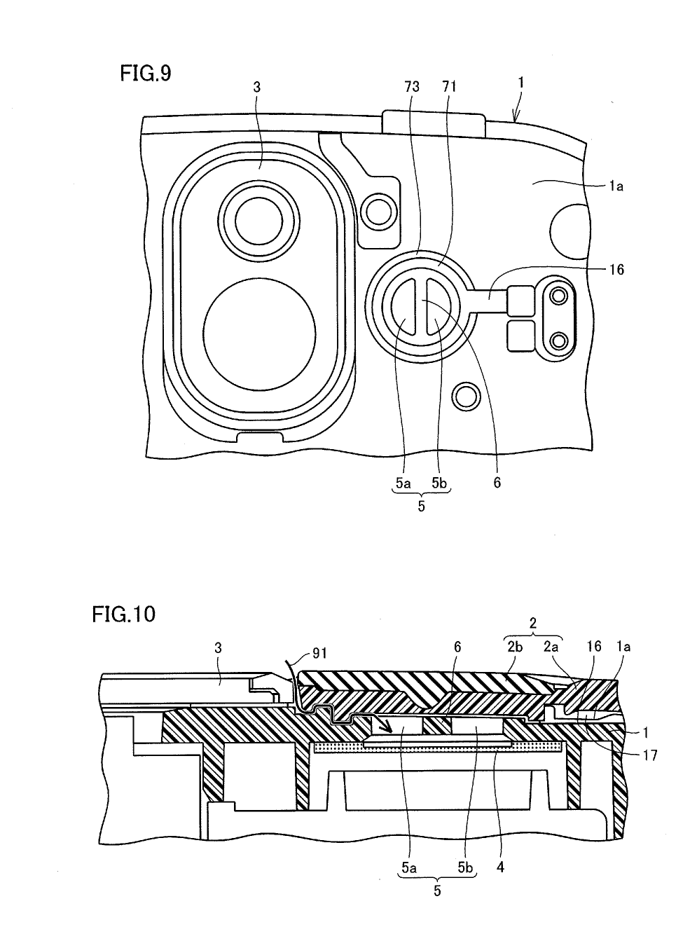

FIG. 7 shows a perspective view of electronic device 101 from which cover 2 has been removed. FIG. 8 shows a Z2 portion in FIG. 7 as being enlarged. FIG. 9 shows a plan view showing a portion in the vicinity of through hole 5 in FIG. 7. A reinforcement beam 6 is located in through hole 5. As reinforcement beam 6 crosses the center of through hole 5, through hole 5 is divided into a portion 5a and a portion 5b. Through hole 5 is substantially circular as a whole. Portion 5a and portion 5b are substantially semicircular. Through hole 5 is also called a “barometric pressure regulation hole.” Groove 16 is located in outer surface la of housing 1 so as to communicate with recess 71 located to surround through hole 5. In this example, groove 16 rectilinearly extends. Projection 73 is discontinuous at a portion where groove 16 intersects with the projection. Therefore, projection 73 is in a C shape.

Sheet 4 is impermeable to water and permeable to air. Such a sheet 4 can be prepared as appropriate based on a known technology. A commercially available product under such names as an “air permeable sheet” and a “waterproof and air-permeable sheet” can be adopted as sheet 4. In particular, sheet 4 located to cover through hole 5 in electronic device 101 is also called a “pressure regulation sheet” or a “barometric pressure regulation sheet” when it aims to regulate a pressure in housing 1.

In the first embodiment, fitting portion 10 where at least one recess and at least one projection are fitted to each other so as to function as a shield in at least a part between first portion 3 and through hole 5 is located. Therefore, in order for a detergent to reach sheet 4 from the outside of electronic device 101, the detergent should follow a path as shown with an arrow 91 in FIG. 10. This path is in a zigzag shape in a cross-sectional view. In the first embodiment, a path of entry of the detergent is thus so convoluted that a probability of the detergent reaching sheet 4 when electronic device 101 is washed with the detergent can be lower. Therefore, according to the first embodiment, degradation in waterproofness due to adhesion of a detergent component to a barometric pressure regulation sheet can be retarded as much as possible in electronic device 101.

Though reinforcement beam 6 rectilinearly extends to pass through the center of through hole 5 in the first embodiment, reinforcement beam 6 may be in a shape other than this shape. Reinforcement beam 6 does not have to be included. By including reinforcement beam 6 in through hole 5, sheet 4 is less likely to break.

In the first embodiment, recess 71 and projection 72 are both in a form of a line. As shown in the first embodiment, “at least one recess” representing one of elements constituting fitting portion 10 may be in a form of a line. “At least one projection” fitted to “at least one recess” may also be in a form of a line.

Though the first embodiment shows the example that recess 71 is in a form of a line, the recess is not limited to a recess in a form of a line but may be in any shape. For example, even rectangular recess 71 can be located to function as a shield in at least a part between first portion 3 and through hole 5. When recess 71 is in a form of a line, it does not have to be rectilinear but may be curved or in an arc shape. This is also applicable to projection 72. The fitting portion is defined by a recess in some shape and a projection in a shape corresponding thereto.

In the first embodiment, housing 1 may include a recess and cover 2 may include a projection, and vice versa.

As shown in the first embodiment, recess 71 and projection 72 may define fitting portion 10 and fitting portion 10 may isolate first portion 3 and through hole 5 from each other. So long as fitting portion 10 isolates first portion 3 and through hole 5 from each other, even though a detergent enters a rear side of cover 2 from a portion in the vicinity of an outer periphery of first portion 3, travel of the detergent is more likely to be stopped by fitting portion 10 before the detergent reaches through hole 5.

Though fitting portion 10 is structured such that one recess 71 in a form of a line and one projection 72 in a form of a line are fitted to each other in the first embodiment, limitation thereto is not intended and two or more recesses in a form of a line may be fitted to two or more projections in a form of a line. A fitting portion where one recess in a form of a line is fitted to one projection in a form of a line corresponds to a single barrier against entry of a detergent, whereas a fitting portion where two recesses in a form of a line are fitted to two projections in a form of a line corresponds to a double-wall barrier. As the number of recesses and projections contributing to fitting is greater, a path of entry of the detergent is more convoluted so that a probability of the detergent reaching sheet 4 can be lower.

As shown in the first embodiment, fitting portion 10 may include a second portion located as at least a part of a shape surrounding through hole 5. Since recess 71 representing one of elements defining fitting portion 10 is seen in FIG. 8, a shape of fitting portion 10 can be known from the shape of recess 71. In this example, fitting portion 10 is located as the shape surrounding through hole 5. In this example, a portion of fitting portion 10 in the shape surrounding through hole 5 corresponds to the second portion.

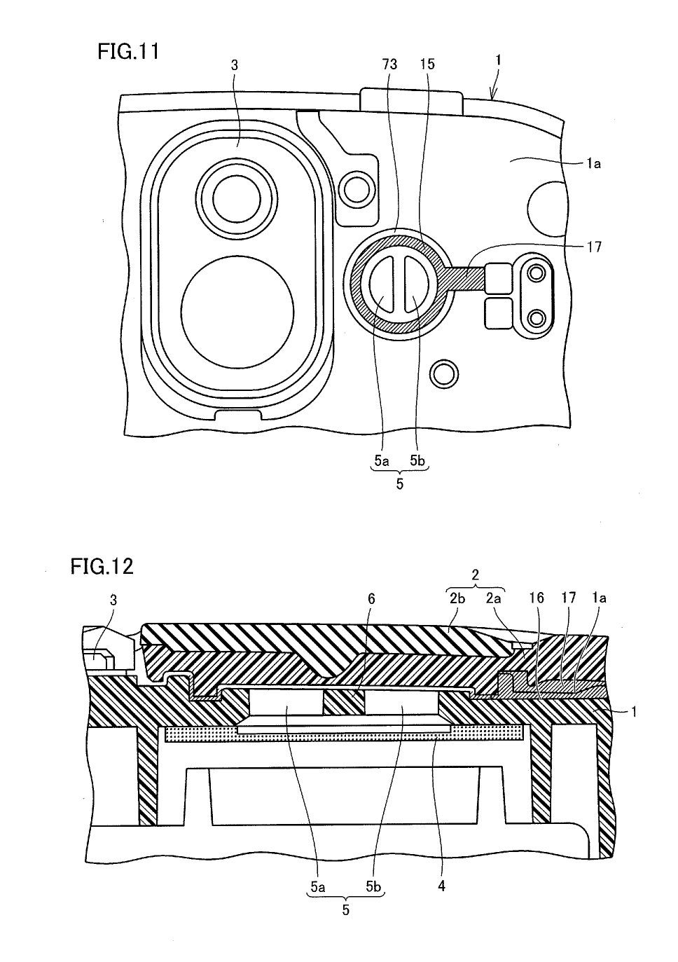

Fitting portion 10 may achieve a fitted state with a gap being left between a bottom surface of recess 71 and a top surface of projection 72 in the second portion. When fitting portion 10 is in the surrounding shape, the gap defines a surrounding space. FIG. 11 shows with hatching at a fine pitch, a surrounding space 15 defined by fitting portion 10. In the example shown in FIG. 11, not only surrounding space 15 but also a first space 17 communicating with surrounding space 15 and extending to an outer side thereof are located. FIG. 11 also shows first space 17 with hatching at a fine pitch. FIG. 12 shows an enlarged cross-sectional view of a portion in the vicinity of through hole 5 in FIG. 11. FIG. 12 also shows surrounding space 15 and first space 17 with hatching at a fine pitch.

As shown in FIGS. 11 and 12, first space 17 may be located between cover 2 and housing 1 so as to extend from the second portion to the outer side of the surrounding shape while the first space communicates with the gap. First space 17 may be in any shape. Surrounding space 15 defined by the gap may be regarded as a bypass for a detergent when the detergent enters a portion around through hole 5. First space 17 may be regarded as a space for letting the detergent escape, which has entered the portion around through hole 5 and has been bypassed. FIG. 13 shows a path of travel of the detergent which has entered the rear side of cover 2. The detergent which has entered the rear side of cover 2 from a boundary between first portion 3 and cover 2 reaches the portion around through hole 5 as shown with arrows 95 and 96 and escapes to first space 17 through at least one of the paths shown with arrows 95 and 96 as being guided into surrounding space 15. An internal space in groove 16 defines at least a part of first space 17. First space 17 may be a space as a passage for letting the detergent escape toward another space. First space 17 may be a space for accepting and storing a detergent.

As shown in FIG. 11, first space 17 may be located on a side of through hole 5 far from first portion 3. Since entry of the detergent into the rear side of cover 2 is more likely to start from a portion around first portion 3, by locating first space 17 on a side of through hole 5 far from first portion 3, direct entry of the detergent into first space 17 instead of surrounding space 15 can be avoided as much as possible.

(Positional Relation Among First Portion, Fitting Portion, and Through Hole)

Some modifications of positional relation among first portion 3, fitting portion 10, and through hole 5 when viewed two-dimensionally will be described below.

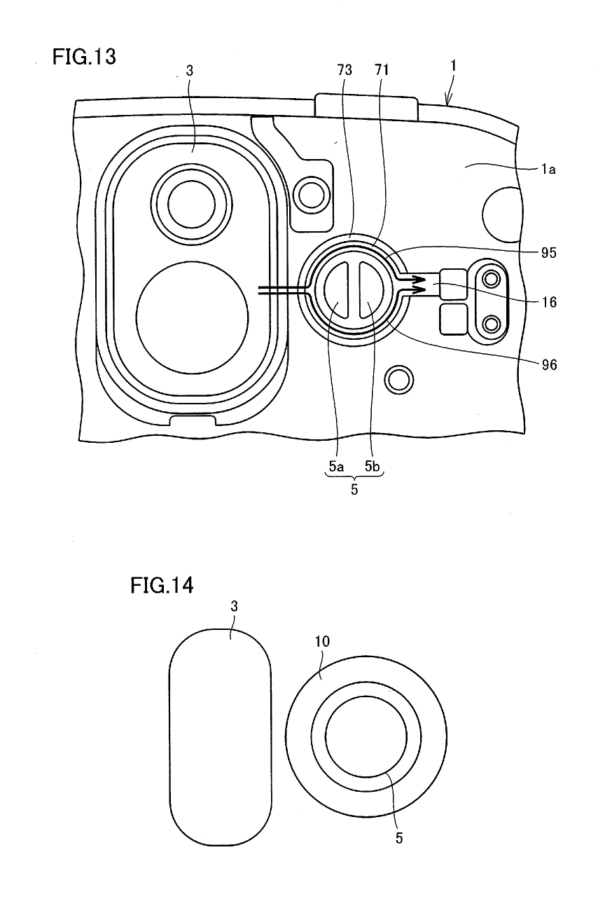

FIG. 14 shows a first example. As shown here, fitting portion 10 may surround through hole 5 in a completely annularly surrounding form. Though the fitting portion is in an annularly surrounding form here, it may be in a surrounding form other than an annular form. A shape of fitting portion 10 is not limited to a completely annular shape surrounding through hole 5 but may be a shape forming a part of the annularly surrounding form. Fitting portion 10 may be, for example, in a C shape. Fitting portion 10 may be, for example, in an arc shape.

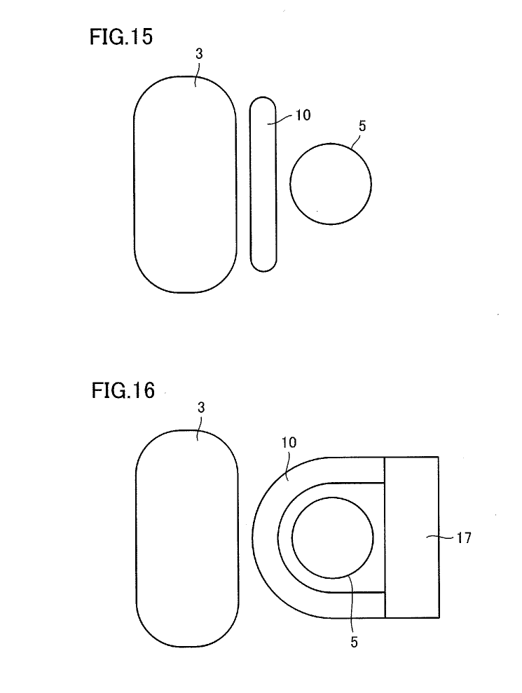

FIG. 15 shows a second example. As shown here, fitting portion 10 may be rectilinear. Rectilinear fitting portion 10 is located to isolate first portion 3 and through hole 5 from each other. Fitting portion 10 does not have to be rectilinear but may be curved or bent.

FIG. 16 shows a third example. In this example, fitting portion 10 is in a U shape and first space 17 is located to connect two ends of the U shape. Thus, fitting portion 10 may be in a form of a line like a kind of non-loop and first space 17 may be located to connect opposing ends of fitting portion 10 to each other. Fitting portion 10 may include a gap defined by a bottom surface of a recess and a top surface of a projection. If there is such a gap, the gap may communicate with first space 17.

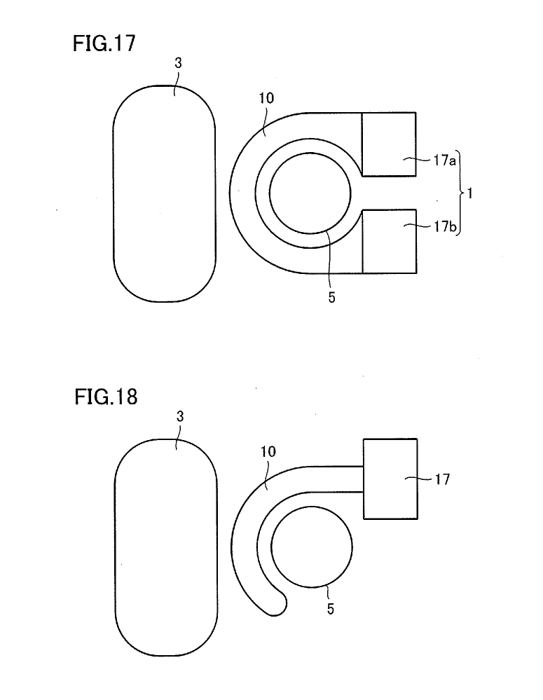

FIG. 17 shows a fourth example. First space 17 may thus be divided into a plurality of sections. In the example shown in FIG. 17, first space 17 is divided into two, that is, a portion 17a and a portion 17b. First space 17 may be divided into three or more sections. Though portion 17a and portion 17b are equal in size to each other in the example shown in FIG. 17, first space 17 may be divided into a plurality of sections and the sections may be different from one another in size.

FIG. 18 shows a fifth example. Fitting portion 10 may thus include a curved portion and a rectilinear portion. First space 17 may thus be located only at one end of fitting portion 10. Combination of fitting portion 10 and first space 17 may thus be asymmetric when viewed two-dimensionally.

Though the first to fifth examples are shown as representative examples here, limitation thereto is naturally unintended. When a space available in an electronic device is limited depending on convenience of layout of other components, positional relation among first portion 3, fitting portion 10, and through hole 5 may be designed as appropriate. Fitting portion 10 may naturally be in an asymmetric shape.

Though through hole 5 has a circular outer geometry in each embodiment, this is merely by way of example and a two-dimensional outer geometry of through hole 5 is not limited to a circular shape.

Though first portion 3 is an elliptical projection in each embodiment, first portion 3 may be in a shape other than an elliptical shape when viewed two-dimensionally. First portion 3 does not have to be a projection. First portion 3 may be a portion not protruding at all as compared with other portions.

Though cover 2 includes first cover portion 2a and second cover portion 2b in each embodiment, cover 2 does not have to be divided into a plurality of sections as such.

Some features in an embodiment above may be adopted as being combined as appropriate. Though description has been given so far by using the term “electronic device,” the electronic device is a broad concept covering, for example, a portable telephone, a portable information terminal, a tablet terminal, a personal computer, a game console, a television receiver, a portable music player, a CD player, a DVD player, an electronic calculator, an electronic organizer, an electronic dictionary, an electronic book reader, a digital camera, a video camera, a radio receiver, a navigation system, and a measurement instrument. The concept of the portable telephone or the portable information terminal includes a smartphone.

Though an embodiment of the present disclosure has been described, it should be understood that the embodiment disclosed herein is illustrative and non-restrictive in every respect. The scope of the present disclosure is defined by the terms of the claims and is intended to include any modifications within the scope and meaning equivalent to the terms of the claims.

1. An electronic device comprising:
a housing including a through hole;
a sheet which is impermeable to water, permeable to air, and located to cover the through hole; and
a cover which is attached to the housing and partially covers an outer surface of the housing while the cover covers the through hole,
the housing including a first portion not covered with the cover even while the cover is attached to the housing, and
the cover and the housing including at least one recess and at least one projection which can be fitted to the recess, in any of the cover and the housing respectively, so as to function as a shield in at least a part between the first portion and the through hole.

2. The electronic device according to claim 1, wherein
the at least one recess is in a form of a line and the at least one projection is in a form of a line.

3. The electronic device according to claim 1, wherein
the recess and the projection form a fitting portion and the fitting portion isolate the first portion and the through hole from each other.

4. The electronic device according to claim 3, wherein
the fitting portion includes a second portion located as at least a part of a shape surrounding the through hole.

5. The electronic device according to claim 4, wherein
the fitting portion achieves a fitted state in such a manner that a gap is left between a bottom surface of the recess and a top surface of the projection in the second portion.

6. The electronic device according to claim 5, wherein
a first space is located between the cover and the housing so as to extend from the second portion while the first space communicates with the gap.

7. The electronic device according to claim 6, wherein
the first space is located on a side of the through hole far from the first portion.
